(19) United States
(12) Patent Application Publication
(10) Pub. No.: US 2020/0319030 A1
(43) Pub. Date: Oct. 8, 2020

(54) TREATMENT OF TARGETS WITH QUANTUM ENTANGLED TRANSMISSION PACKAGES

(71) Applicant: Gustav Hudson, Fallbrook, CA (US)

(72) Inventor: Gustav Hudson, Fallbrook, CA (US)

(21) Appl. No.: 16/833,586

(22) Filed: Jun. 4, 2020

Related U.S. Application Data
(60) Provisional application No. 62/828,299, filed on Apr. 2, 2019.

(51) Int. Cl. G01J 3/44; H01S 5/042; H01S 5/343; G01J 3/18; G01J 3/10

(52) U.S. Cl. CPC G01J 3/4406; H01S 5/042; G01J 3/10; G01J 3/18; H01S 5/3432

(57) ABSTRACT

An improvement is made to a non-Raman spectroscopy method and apparatus in which a quantum entangled transmission package formed in a quantum well in a laser is directed to a target and in which the apparatus receives emission packages from the target. A control circuit triggers the laser to emit a laser beam. The transmission package is sent via the laser beam by an emission fiber and the emission package is received by a collection fiber. The collection fiber and the transmission fiber may be included in a Raman probe. The collection fiber provides an input to a monochromator comprising a diffraction grating. The diffraction grating is constructed to permit selection of any of a wide range of wavelengths. A spectrometer receives an output from the diffraction grating. The spectrometer output is measured by a photomultiplier to provide an input to the control module. A number of different spectra are selectively generated. Also, the transmission package may be formed with a power level to affect structure of a preselected target.

### FIELD

The present subject matter relates to non-Raman spectroscopy utilizing formation of a novel package of entangled energy and particles in addition to photons in a sublasing state and triggering a laser to provide a laser beam carrying the package to treat a target.

### BACKGROUND

Quantum entanglement of photons is a well-known phenomenon that is well understood in comparison to many emerging concepts in the field of quantum physics. The existence of dark matter and dark energy is well known, but its nature and composition are not known. The prior art has not made use of other entities beyond photons in creation of entangled particles and energy. Entangled photons are useful in that they provide for what Einstein called, “spooky action at a distance.” In a pair of entangled particles, the state of one particle is a function of the other even when the particles are separated by a large distance.

Quantum entanglement of photons is a basic phenomenon in the creation of qubits, which form a quantum computer. The photons are entangled. Unentanglement is not a part of operation of a quantum computer. Quantum entanglement of photons is also a basis for secure, unhackable communications. Current applications do not extend the scope of entanglement to a plurality of different forms of energy and particles. The number of applications utilizing quantum entangled photons is limited. Other areas could benefit from new forms of entanglement. Entanglement is not established as a mechanism used in the treatment of cancer. Laser beams and photon beams are well-known for cancer treatment. Beams of entangled particles are not known for cancer treatment.

There is a long-felt need to provide a way that is not prohibitively expensive to determine if a tumor is cancerous without having to break a surface of the tumor. At the present time, the prevalent procedure for diagnosis is a biopsy. The tumor is penetrated, and tissue is removed. Various forms of treatment are used in response to a diagnosis of cancer. Biopsy is a significant diagnostic tool. The necessity of a less invasive tumor biopsy device is preferable as needle biopsy of a cancerous tumor risks dispersion of cancerous cells from the sample site upon withdrawal of the biopsy needle from a target tumor specimen. A biopsy may cause cancerous cells to be released from the tumor into the bloodstream. Currently, prior art optical means for analyzing tumors without a biopsy require a plurality of specialized optical fibers. The optical fibers extend into a Raman probe. The ends of the exultation fiber and collection fiber have sapphire lenses formed thereon. These probes may cost $800.00 each. They cannot be sterilized. They must be disposed of after a single use.

An additional required element of apparatus is a diffraction grating. Diffraction gratings are used in order to provide different wave lengths for illumination of a sample and obtain anti-Stokes and Stokes lines.

Past publications in the field have alluded to the treatment of human tissue, but an apparatus or a method has not been defined. United States Published Patent Application No. 200501430791 purported to disclose a process for treating a biological tissue by irradiating tissue with photonic radiation. The rejection of this application stated that an unpredictable amount of experimentation was required as to a number of aspects of the claimed matter. The rejection also observed that no working examples were provided.

Hameroff, S. R., A new theory of the origin of cancer: quantum coherent entanglement, centrioles, mitosis, and differentiation, Biosystems. 2004 Nov;77(1-3):119-36, accessed at https://www.ncbi.nlm.nih.gov/pubmed/15527951, describes the impairment of quantum entanglement among microtubule-based mitotic spindles and centrioles as a mechanism that can cause cancer.

### SUMMARY

Briefly stated in accordance with the present subject matter an improvement is made to a non-Raman spectroscopy method and apparatus in which a quantum entangled transmission package formed in a quantum well in a laser is directed to a target and in which the apparatus receives emission packages from the target. A control circuit triggers the laser to emit a laser beam. The transmission package is sent via the laser beam by an emission fiber and the emission package is received by a collection fiber. The collection fiber and the transmission fiber may be included in a Raman probe. The collection fiber provides an input to a monochromator comprising a diffraction grating. The diffraction grating is constructed to permit selection of any of a wide range of wavelengths. A spectrometer receives an output from the diffraction grating. The spectrometer output is measured by a photomultiplier to provide an input to the control module. A number of different spectra are selectively generated. Also, the transmission package may be formed with a power level to affect structure of a preselected target.

### BRIEF DESCRIPTION OF THE DRAWINGS

FIG. 1 is a diagram of a system incorporating the present subject matter;

FIG. 2 is an illustration of entanglement of photons;

FIG. 3 is a simplified illustration of a quantum well laser;

FIG. 4A is a diagram of one form of quantum well laser diode suitable for use in the laser of FIG. 1;

FIG. 4B illustrates a further form of laser diode comprising a separate confinement laser quantum well;

FIG. 5 is a timing diagram illustrating the sublasing current and the triggering current applied to the laser diode;

FIG. 6 is a diagram of spectral scanning apparatus including a diffraction grating assembly according to the present subject matter;

FIG. 7 is a graph of results obtained in providing particles from the laser versus input power;

FIG. 8 illustrates a reaction of components of the transmission package with a sample;

FIG. 9 illustrates disentangled particles affecting the target;

FIG. 10 is a representation of normal and cancerous cells on a microscope slide;

FIG. 11 a diagram of the structure of a DNA double helix in an exemplary metastatic tumor;

FIG. 12 illustrates a device used in detection of tumors;

FIG. 13 is a graph showing spectra which differentiate normal cells from cancer cells;

FIG. 14 is a diagram showing one embodiment of the present subject matter in use to treat a patient;

FIG. 15 illustrates a molecule to be modified by the transmission package included in the laser beam;

FIG. 16 illustrates a sample which has been modified by the transmission package;

FIG. 17 is a chart of spectra indicative of differences that may occur between the original molecule of FIG. 15 and the modified molecule as seen in FIG. 16;

FIG. 18 is a block diagram of another embodiment of the present subject matter;

FIG. 19, consisting of FIGS. 19A, 19B, and 19C, comprises charts illustrating nominal results obtained from the spectrophotometer.

### DETAILED DESCRIPTION

The present subject matter deals with phenomena that are only beginning to be understood. For the sake of conciseness in the present description, these phenomena are treated as being known and understood. However, the present subject matter is not bound by any particular theory. The implementation of the present subject matter does not depend on the correctness of any particular theory. Baryonic matter, i.e., what has traditionally been considered to be all matter, is only 2% of matter in the universe. A method and apparatus are described which produce repeatable operation and results. Directions are provided to enable those skilled in the art to practice the invention. The present subject matter is described in both medical and nonmedical contexts.

The demonstrable behaviors of OCDM and OCDE on a nano scale hold universally true as attributes observed on a macro scale in the cosmos. Many heretofore impossible scientific and physics uses may come out 1 of the present subject matter. Secure communications and a non-decoherent quantum computer may be developed from the acquisition of OCDM and OCDE, as the quantum particle duality in combination with time differential enables information to be transferred securely in same time increments or stored in time with complete security for future retrieval. Applications for use of OCDM and OCDE have not been fully explored and are only now found with Low Energy Laser Spectroscopy (LELS) according to the present subject matter.

OCDM and OCDE may be acquired by many other means including those described here; through laser emissions, diode emissions, quantum tunneling, acoustics, electronic pulse, oscillation, spectroscopy of all types, Raman spectroscopy, Stokes, anti-Stokes, scalar field, scalar wave, microscopy, optical generating, optical signals, optical pulses, semiconductor, super cooled semiconductors, manipulation of photons, manipulation of particles, material excited by excitation fields, superposition, super symmetry, signal beam, wave energies, wave packages, solar and magnetic activity, unknown particles and fields, unknown waves, wave packages, wave energies, harmonic frequencies, vibrational energies, holographic display, atmospheric audio and spectral display, atomic and sub atomic particles, supercooled atomic and subatomic particles, and particle duality states, for the acquisition or use of OCDM and OCDE. In LELS spectroscopy the spectral peaks are similar to Stokes and anti-Stokes, there are no reciprocal anti-Stokes responses, and no Rayleigh waves. This is because there are no photons detected. There is no scattering of photons or energies. Although the present subject matter utilizes Raman probes, Raman spectroscopy is not utilized and Raman scattering is not measured.

In a measurement mode in accordance with the present subject matter, a spectrometer performs spectroscopic analysis for detecting 5-fluorouracil (5 FU), C₄H₅FN₂O₂. The carbon-fluorine bond is the strongest bond next to the hydrogen bond. 5 FU is a compound commonly used in chemotherapy. 5 FU is injected and has uptake into a tumor through chemotherapy. 5 FU enters cancerous cells. Spectroscopic analysis can detect 1 ppm in solution. 5 FU is injected into a tumor. 5 FU enters cancerous cells.

### Overview

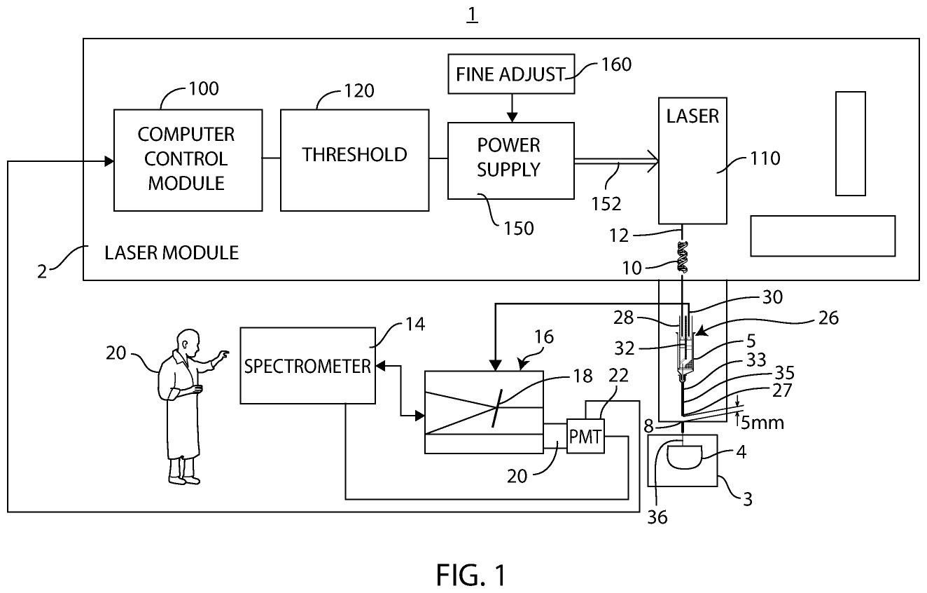

FIG. 1 is a diagram of a system incorporating the present subject matter. For purposes of the present description, discrete elements of the system are illustrated. In practice, functions may be incorporated in larger subsystems or may be distributed over more components.

The system 1 comprises a laser module 2, a target module 3, and a Raman probe 5. In a treatment mode, the laser module 2 provides a laser beam 12 carrying a transmission package 10 of entangled particles and energy further described below. The target module 3 holds a sample 4. The sample 4 may comprise human tissue in vivo or in vitro or may comprise inanimate matter. The laser module 2 sends the transmission package 10 to the sample module 3. The sample 4 interacts with the transmission package 10 to change the structure of the sample 4. The Raman probe 5 directs the transmission package 10 to the sample 4 and collects emissions from the sample 4 and sends the emissions to a monochromator 16. A diffraction grating 18 constructed in accordance with the present subject matter provides both anti-Stokes and Stokes responses through a lens 20 to a photomultiplier 22. The outputs of the photomultiplier 22 are connected to the laser module 2 to close a control loop.

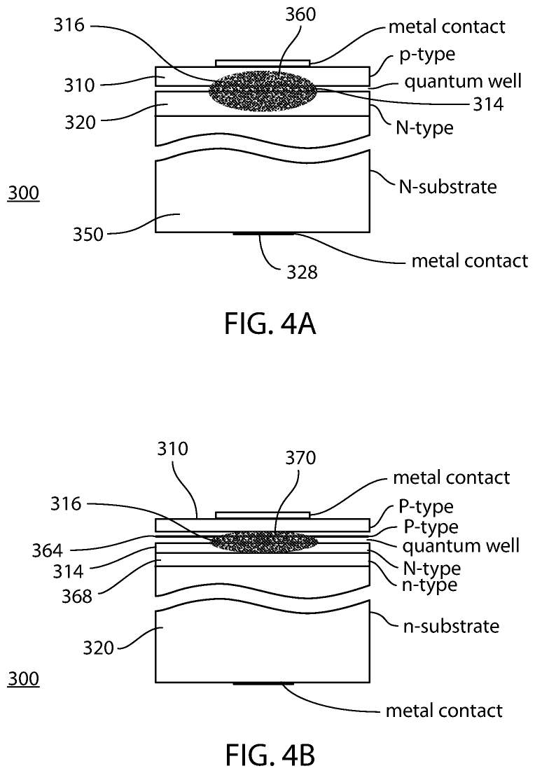

In the laser module 2, a computer control module 100 provides a sequence of signals commanding operation of the laser module 2. The computer control module 100 may be, for example, a personal computer, a server, or a cloud resource. Many other forms of providing a sequence of output voltages, output currents, or other forms of command signal may be used in other embodiments. The laser beam 12 is provided from a laser 110. The laser beam 12 exits from a quantum well 316 (FIG. 4A) in the laser 110. The magnitude and the duration of the beam 12 produced by the laser 110 are controllable by settings in the computer control module 100. As further described below, a user may adjust settings to define power inputs to the laser 12. The operating parameters provided by the computer control module 100 may be adjusted by the user 20.

The computer control module 100 provides a signal to a threshold circuit 120. Use of the threshold circuit 120 is optional. However, the threshold circuit 120 provides the option of selectively connecting other control modules (not shown) for use in the laser module. The threshold circuit 120 may also be used to provide outputs to additional stages (not shown). The threshold circuit 120 may comprise a universal connection hub. The threshold circuit 120 is connected to receive the output of the photomultiplier tube 22.

The threshold circuit 120 couples a signal from the computer control module 100 to a power supply 150. The threshold circuit 120 may provide no output when the laser 110 is not operated. When operated, the laser 110 is selectively biased in a sublasing state or triggered to emit the laser beam 12. The threshold circuit 120 provides an output of a first level or a second level. The power supply 150 selectively supplies the biasing current or the triggering current in response to the first level or the second level respectively. A fine adjust circuit 160 may refine the value of current values provided by the power supply 150. In one preferred embodiment, the power supply 150 is connected to the laser 110 via a 12-pin ribbon 152. The power supply 150 provides the sublasing biasing current to the laser 110 when the input from the switching circuit 130 is at the first level. The power supply 150 provides the triggering current to the laser 110 when the input from the switching circuit 130 is at the second level.

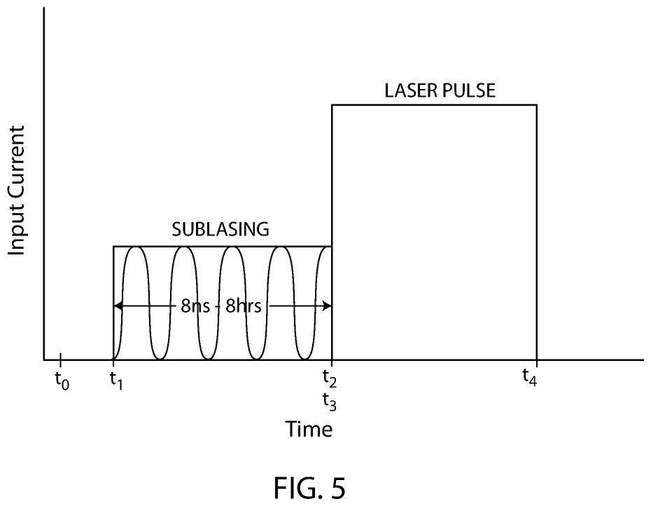

When the laser 110 is biased at the sublasing level, the transmission package 10 is formed in a quantum well 316 (FIG. 4A) of the laser 110. Forming the transmission package 10 is analogous to building up charge in a capacitor. This operation and structure are further described with respect to FIG. 4 and FIG. 5 below.

### The Raman Probe

The Raman probe comprises a first fiber optic cable, excitation cable 28. The fiber optic cable 28 preferably comprises an RF shielded, internally connected, coated fiber optic cable. A suitable diameter for the fiber optic cable 28 is 100 microns (100 μ). The fiber optic cable 28 is terminated at the Raman probe 26 manufactured for passage of 532 nm radiation using a bandpass filter and dichroic filter 32. The Raman probe 26 has a standard focal lens 27 with 5 mm convergence. The energy passed through the Raman probe 26 interacts with the sample 4. Excitation of the sample 4 by the transmission package 10 results in an emission package 36 being transmitted from the sample 4.

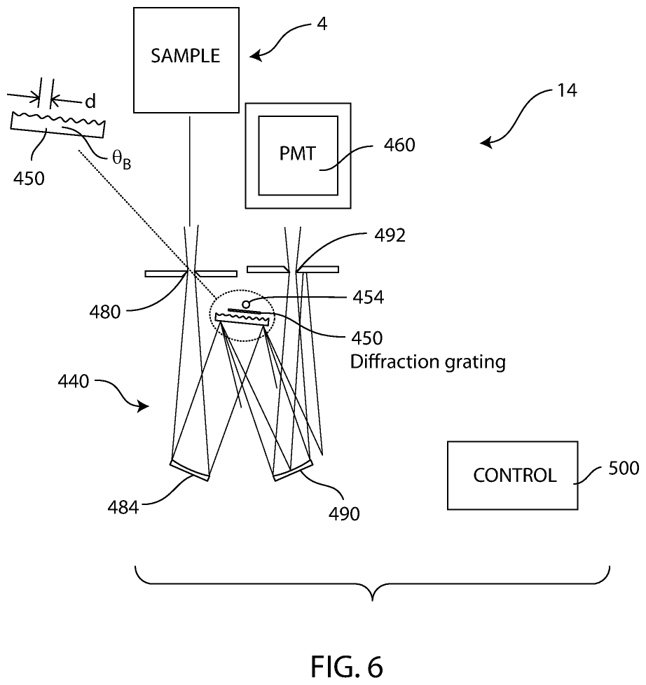

A second fiber optic cable, a collection fiber 30, is an RF shielded coated fiber optical cable preferably having a diameter of 200 μ. The emission package 36 provides an input to the Raman probe 26 which is received by the collection fiber 30. The portion of the emission package 36 which is received by the collection fiber 30 is referred to as the emission package output 38. The collection fiber 30 provides the emission package output 38 for spectrometry. The collection fiber is coupled to the monochromator 16. The monochromator 16 operates as further described with respect to FIG. 6 to provide a scanned spectrum to the photomultiplier tube 22. The spectrum output from the photomultiplier tube 22 is provided to the spectrograph 114.

The transmission fiber 28 and the collection fiber 30 may each communicate with a single, two-way fiber 33. The fiber 33 may be housed in a syringe 35. Dark matter energy goes to a single fiber at a tip of the Raman probe 5 and to the collection fiber 30 outside of time.

In an alternative embodiment the transmission fiber 28 and the collection fiber 30 are each included in a separate Raman probe. A first Raman probe 26a irradiates the sample and is not connected to the spectrograph or photomultiplier. The collection fiber 30 is located in a second Raman probe 26b. Probe 26b does not use the laser. Probe 26b is used as a collector and is run through the spectrograph, the CCD, and the photomultiplier to produce computer generated spectra. These spectra energies from probe 26a irradiated sample cannot be detected by probe 26b at 22 ½ degree angle to a 90 degree angle. The probe 26b can only collect energies from irradiated samples at 180 degrees. The collection fiber 30 receives energies along a direct line. The collection fiber 30 does not respond to scattering.

In order to produce the transmission package, the laser 110 acquires and utilizes unknown particles which may include omnipresent cosmological dark matter particles (OCDM) and omnipresent cosmological dark energy (OCDE) together with photons, electrons, particles, waves, wave packages, fields and energies in quantum entanglement. The laser 110 produces a low energy excitation in a quantum well region. magnetic activity, unknown particles and fields, unknown waves, wave packages, wave energies, harmonic frequencies, vibrational energies, holographic display, atmospheric audio and spectral display, atomic and sub atomic particles, supercooled atomic and subatomic particles, and particle duality states, for the acquisition or use of OCDM and OCDE.

When the power supply 150 provides triggering current to the laser 110, a triggering pulse causes emission of the laser beam 12 carrying the transmission package 10. The transmission package 10 is directed to collide with the sample 4. Particles from the transmission package 10 will interact within the sample 4. Entangled energy is separated from photons in the transmission package 10. The laser beam is used in a number of ways. The laser beam 12 may be aimed at the target 4 for spectral analysis for the presence of 5-fluorouracil (5 FU). The laser beam 12 may also be directed for altering the structure of the sample 4.

One form of altering the structure of the sample 4 comprises killing cancerous cells in a tumor. The embodiment of FIG. 1 may be used for cancer treatment or for modification of inanimate material. The laser beam 12 may also be used to alter inanimate molecules. It is believed that one phenomenon that causes particles of elements to comprise the element is defined by dark matter in the particle. The transmission package 12 disrupts the relationship between the definition of the substance and its associated dark matter component.

As seen in FIG. 1, in accordance with the present subject matter, the transmission package 10 is created in a quantum well of a solid-state laser. At a later time, the transmission package 10 is imposed on the laser beam 12 for direction at the sample 4. According to the present subject matter, photon entanglement is utilized. However, additional entanglement of other entities also occurs. It is believed that the other entities include omnipresent cosmological dark matter particles (OCDM) and omnipresent cosmological dark energy (OCDE). The mechanism of this entanglement is not understood at the present time.

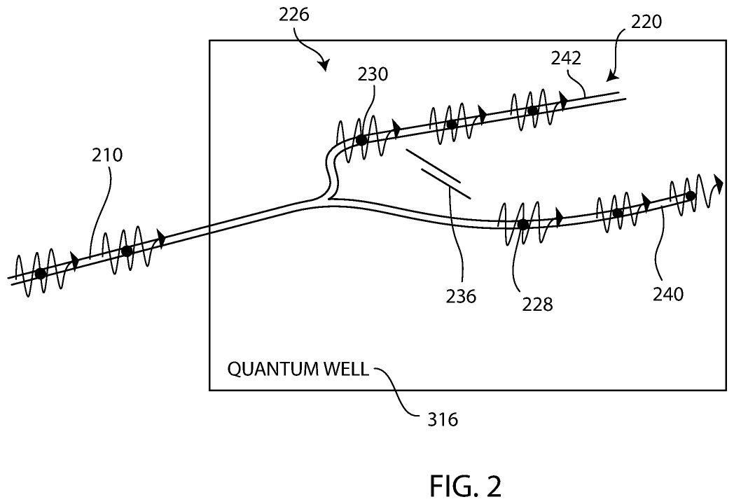

FIG. 2 is an illustration of entanglement of photons. Photon entanglement is done in the contexts of quantum computers and secure, encrypted communications. This is not the same process as in the present subject matter. FIG. 2 is intended to show a known mechanism for entanglement in order to convey a qualitative description of the sort of entanglement which occurs in the quantum well 316 (FIG. 4A). A radiation beam 210 is provided from the laser 110 (FIG. 1) to interact in the quantum well 316. The quantum well 316 is in a structure further described with respect to FIG. 4A and FIG. 4B. While the laser 110 is biased at the lower current level, the radiation beam 210 is converted to a stream 220 of entangled photons pairs 226 within the quantum well 316. Each photon pair 226 comprises a first photon 228 and a second photon 230. A line 236 represents quantum entanglement between the first and second photons 228 and 230. The first and second photons 228 and 230 are illustrated as being in first and second beams 240 and 242 respectively.

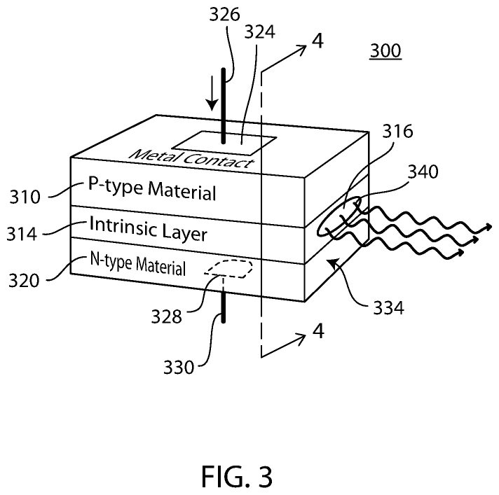

FIG. 3 is a simplified illustration, drawn to an arbitrary scale, of a quantum well laser 300. A quantum well laser is a laser diode in which an active region of the device is so narrow, e.g., <10 nm, that quantum confinement occurs. Broadly speaking, quantum confinement is a restriction on the motion of randomly moving electrons present in a material to specific discrete energy levels rather than to quasi continuum of energy bands. Quantum confinement results from electrons and holes being squeezed into a dimension that approaches a critical quantum measurement, called the exciton Bohr radius.

Laser diodes are formed in compound semiconductor materials that are able to emit light efficiently. A laser diode has an intrinsic additional active layer, i.e., an undoped layer 314. The layer may be, e.g., gallium arsenide, only a few nanometers thick, sandwiched between the P and N layers 310 and 320 respectively, effectively creating a PIN, P-type/Intrinsic/N-type, diode. It is in the intrinsic layer 314 that the laser light is produced. The laser diode passes a large amount of forward current from P to N, much greater than that used in an LED. The Laser diode will only produce laser light when operated at above about 80% of its maximum current.

The electron flow to the N-P semiconductor produces a quantum tunneling of electrons into the active region of the laser quantum well 316 creating a sub lasering low energy level, acquisition and propagation of particles, photons, electrons, OCDM and OCDE energies and waves within a quantum entangled state. The paired states are energetically favored, and electrons go in and out of those states preferentially.

The wavelength of the light emitted by a quantum well laser is determined by the width of the active region rather than just the bandgap of the material from which it is constructed. Much longer wavelengths can be obtained from quantum well lasers than from conventional laser diodes using the same semiconductor material. Since a quantum well has a stepwise form of its density of states function, its efficiency is greater than a conventional laser.

The quantum well laser 300 comprises a P-type first layer 310, an intrinsic layer 314 and an N-type second layer 320. Emission exits an output surface 340 in the intrinsic layer 314, which comprises a quantum well 316. A metal contact 324 on an upper surface of the P-type layer 310 provides input current to the quantum well laser 300 via a first lead wire 326. The first lead wire 326 is coupled to the power supply 150 (FIG. 1). A second metal contact 328 is located on a lower surface of the end type layer 320. A lead wire 330 completes the circuit with the power supply 150. In the quantum well laser 300 current flows through each of the layers 310, 314, and 320. Light exits from a side 334 of a single layer, namely the intrinsic layer 314 comprising the quantum well 316.

FIG. 4A is a diagram of one form of quantum well laser diode suitable for use in the laser 110 of FIG. 1. FIG. 4B illustrates a further form of laser diode comprising a separate confinement laser quantum well. FIG. 4A and FIG. 4B are each a cross sectional elevation of the quantum well laser diode 300 taken along line 4-4 of FIG. 3. The same reference numerals are used to denote corresponding elements in FIG. 3. FIG. 4A and FIG. 4B each illustrate the laser quantum well region 316. The quantum well 316 is a region of quantum tunneling and weak diode effect, where secondary quantum tunneling and secondary wave package and entanglement occur. The present subject matter is not limited to a specific configuration.

In FIG. 4A the N-type second layer 320 is formed on top of an N-type substrate 350. The metal contact 328 is formed on a lower surface of the N-type substrate 350. Embodiments including a substrate are used in practical applications. A shaded oval 360 in FIG. 4A shows a field surrounding the quantum well 316. FIG. 4B illustrates a further form of laser diode 300 comprising a separate confinement laser quantum well 370. The separate confinement laser quantum well 370 is intermediate the P-type first layer 310 and the N-type second layer 320. An additional P-type layer 364 is placed between the P-type first layer 310 and the intrinsic layer 314. An additional N-type layer 368 is formed between the intrinsic layer 314 and the N-type second layer 320. The shaded oval in FIG. 4B illustrates confinement of the fields in the quantum well 370 between the P-type first layer 310 and the N-type second layer 320. The laser quantum well 370 also comprises a region of quantum tunneling and weak diode effect in laser quantum well 370, where secondary quantum tunneling and secondary wave package and entanglement occur.

FIG. 5 is a timing diagram illustrating the sublasing current and the triggering current applied to the laser diode. FIG. 5 is used to describe the operation in the present subject matter in which the transmission package 10 is formed and sent via the laser beam 12 to collide with the target 4 (FIG. 1). The laser 110 in FIG. 1 corresponds to the laser 300 in FIG. 3. In the description of FIG. 5, reference will be made to the quantum well laser 300. A first stage is a sublasing stage and a second stage is lasing stage. FIG. 5 is a timing diagram illustrating commanding the start and finish of the first stage and the start and finish of the second stage. At time to the laser module 2 may be initialized and the sample 4 may be set up in the apparatus. In the first stage, which starts at time t₁, the laser diode 300 (FIG. 3) is biased by an input current into a sublasing stage. This sublasing stage corresponds to the first state described with respect to FIG. 1. Electrons go in and out of a quantum state, creating a quantum energy environment.

In a sublasing stage, current flows through the laser diode 300, but light is not transmitted in the form of a laser beam. In the sublasing state, a laser may produce a glow. In the first stage current flow from the power supply 150 provides electrons to the quantum well 316. The electrons will be converted to photons. Photons will be quantum entangled. In the first stage other entities become entangled. In this manner the transmission package is formed. The system is at rest at time t₀. Operation is initiated at time t₁. The threshold circuit 120 is connected to provide the first level input to the power supply 150, which in turn provides the first current level to the laser 110. The first stage is ended at time t₂. The t₁-t₂ interval in nominal embodiments can range anywhere from 8 ns up to 8 hours.

The lasing stage begins when the laser 110 is triggered at time t₃ at the end of the t₁-t₂ interval. The primary component of an interval between time t₂ and time t₃ is the time to fire the laser 300. Time t₂ and time t₃ may occur simultaneously. The laser triggering pulse ends at time t₄. The laser beam 12 carries the transmission package 10 to the target 4 in order to produce reactions with the target 4 in various ways described below.

There is no internal trigger. In one form an exposure time is 0.44 seconds and a cycle time is 0.44 seconds. The exposure time and the cycle time are represented by the wave in the envelope from t₁ to t₂. Time gating does not need to be used because there is no necessity to eliminate Rayleigh noise.

FIG. 6 is a diagram of spectral scanning apparatus including a diffraction grating assembly according to the present subject matter. FIG. 6 is a diagram of the spectrometer 14 of FIG. 1. The spectrometer 14 comprises a monochromator 440 including a novel blazed diffraction grating 450 providing a wide range of spectral measurements to generate peaks similar to anti-Stokes and Stokes responses. Spectral responses are measured by a photomultiplier tube 460. Lines analogous to Stokes lines indicate radiation of particular wavelengths present in the line spectra associated with fluorescence. Lines analogous to anti-Stokes lines are of shorter wavelength than that of the light that produces them. Energies have a spectrographic effect,

After entities interact with the sample 4, radiation enters an entrance slit 480 and is reflected by a collimating mirror 484. Radiation is directed to the diffraction grating 450. The diffraction grating 450 is mounted to an angular displacement device 454. The angular displacement device 454 may be controlled by the computer control module 100 of FIG. 1 or control unit 500 located in the spectrometer 14. The angular displacement of the angular displacement device 454 determines the wavelength that is reflected to a camera mirror 490. Radiation exits an exit slit 492 and is measured by the photomultiplier tube 460.

In the preferred form, the diffraction grating 450 is a blazed grating. A blazed diffraction is optimized to achieve maximum grating efficiency in a given diffraction order. A blazed grating has a constant line spacing d, between ridges. Spacing d determines the magnitude of the wavelength splitting caused by the grating. The grating lines possess a triangular, sawtooth-shaped cross section, forming a step structure. The steps are tilted at the so-called blaze angle θ_{B} with respect to the grating surface. Accordingly, the angle between step normal and grating normal is θ_{B}. In the present illustration, the diffraction grating 450 has a gradient of 1200, i.e.,1200 grooves per mm, and a 500 blaze, i.e., wavelength λ of 500 nm. The “Blaze Wavelength” is the wavelength for which the blazed grating is most efficient. With these values of gradient and blaze, the full range of wavelengths are from 2,500 nm. anti-Stokes-like peak to 5,000 nm. Stoke like peak is accommodated with a single grating.

Prior art gratings providing for a wide range of refractive wavelengths utilize a triangle having three grating surfaces and positioned so that one grating is reflecting an incoming beam for each of the range of values.

A 1200 gradient is not generally used for Raman spectroscopy. However, in the spectrometer 14, energy shift is measured. The spectrometer 14 generates results for a spectral range of 0-3500 nm. This range includes 2800-3200 Å which is a signature range for a double carbonyl bond.

In the present embodiment, 5 FU spectroscopy is performed. 5 FU comprises RNA and DNA protein. The molecular structure of 5 FU is shown in Table I

TABLE I

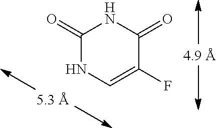

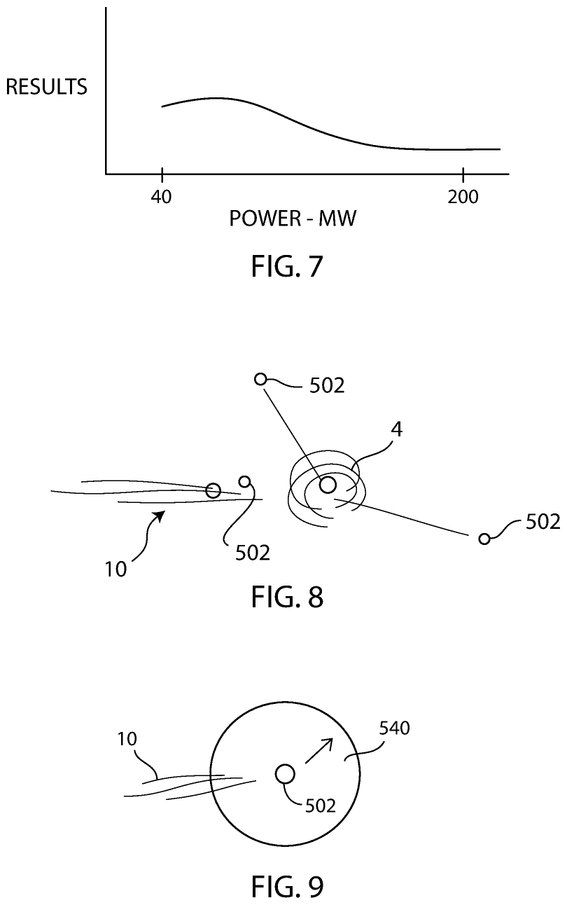

FIG. 7 is a graph of results obtained in providing particles from the laser 300 versus input power (FIG. 3). The energy to drive the laser 300 in a nominal embodiment may range from 40 mw to 200 mw. The preferred power input may be determined empirically based on the following principles. The current to drive the laser 300 must provide a supply of electrons that will be converted to photons. Excess electrons will make too many photons. In this context “too many” means that the photons cannot be separated at the sample 4. Excess photons will also flush out other entangled particles. Once flushed out the particles cannot return to the transmission package 10. The output of the laser 110 (FIG. 1) can be controlled from 200 mw down to 0.001 mw.

In FIG. 7 the axes have arbitrary scales. The abscissa is power. The ordinate is results in terms of detected energy for a given sample. It has been found that it is preferable to power the laser at the lower range of the input power level. It is important to provide low energy particles. This graph will instruct those skilled in the art in conducting the empirical determination of input power. RNA and DNA are destroyed by irradiation

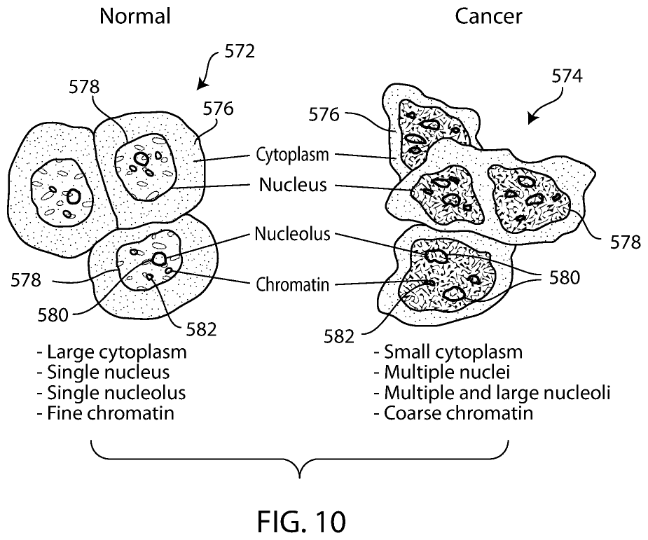

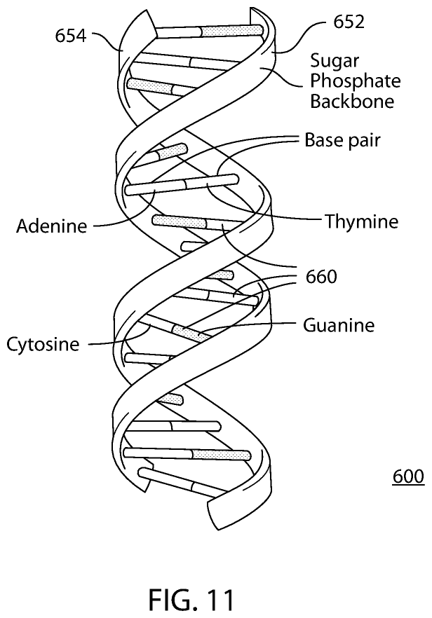

FIG. 8 illustrates a reaction of components of the transmission package 10 with the sample 4. The transmission package 10 collides with the sample 4. The entangled energy in the present embodiments is not subject to properties of known energy except for x-rays. Photons 502 in the transmission package 10 will be reflected, refracted, or absorbed. The transmission package 10 is capable of going through solid objects. At lower energy levels, photons 502 will become disentangled. Disentangled particles affect substances. For example, the disentangled particles affect the structure of RNA and DNA in cancerous cells so that they cannot reproduce. This is discussed further with respect to FIG. 10 and FIG. 11 below.

FIG. 9 illustrates disentangled particles affecting the target. Energy of entangled subatomic particles are common to all baryonic materials. Baryonic materials came into existence 2,000,000,000 years after the Big Bang. The disentangled photons will also affect molecular structure. The mechanism and theory of modification of molecules is not yet known. It is believed that elements have a key to determine what structure their quarks will take. By modifying the dark energy, the structure of the molecule may be changed. FIG. 9 illustrates a transmission package 10 entering an atom 540. Disentangled photons 502 collide with dark matter to affect the relation of the dark matter with the structure of the atom 540. While the theory is not yet understood, this is a repeatable phenomenon.

FIG. 10 is a representation of normal and cancerous cells on a microscope slide illustrating normal cells 572 and cancerous cells 574. Malignant cells differ in physical structure. The nucleus may become more irregular. In normal cells, the nucleus is often round or ellipsoid in shape, but in cancer cells the outline is often irregular. Different combinations of abnormalities are characteristic of different cancer types. Nuclear appearance can be used as a diagnostic marker with regard to certain types of cancer.

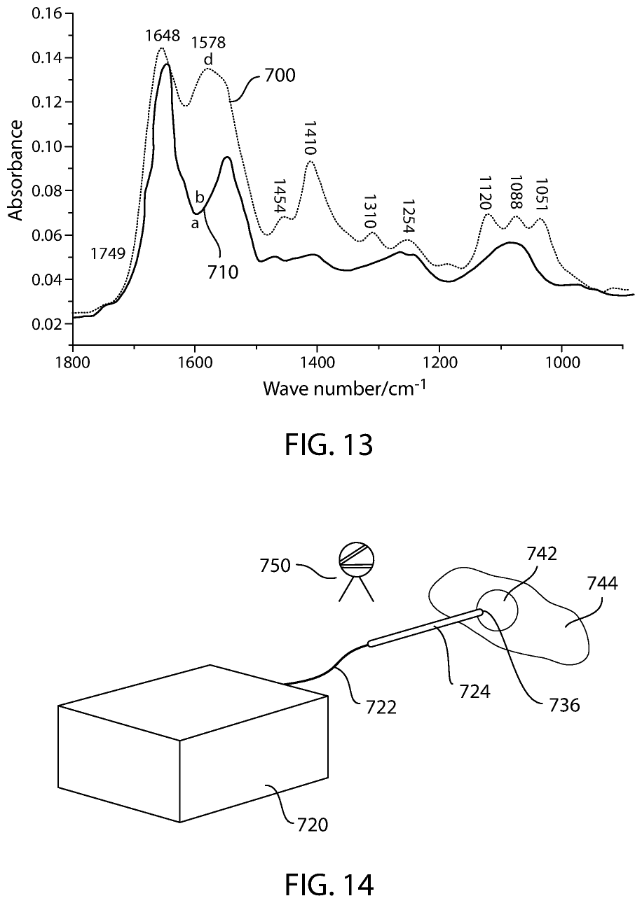

Each cell comprises cytoplasm 576 and a nucleus 578. Each normal nucleus 578 comprises a nucleolus 580. Cancerous cells comprise multiple, enlarged nucleoli. The nucleolus 580 can become enlarged. Chromatin 582 is within each nucleolus 580. In a normal cell 572, the chromatin 582 is fine. In a cancerous cell 574, the chromatin 582 is coarse. Chromatin may aggregate or disperse. Spectroscopy is now recognized to be of significant potential in distinguishing normal tissue from pathological tissue. In accordance with the present subject matter an operative form of distinguishing normal cells from cancerous cells by spectroscopy is presented. Spectroscopic analysis is discussed with respect to FIG. 13.

FIG. 11 a diagram of the structure of a DNA double helix 600 in an exemplary metastatic tumor. The DNA double helix 600 comprises backbone helixes 652 and 654. Base pairs 660 are disposed between the backbone helixes 652 and 654. The base pairs 660 comprise combinations of the basic building blocks adenine, cytosine, thymine, and guanine, commonly referred to as A, C, T, and G respectively.

In normal mitosis chromosomes replicate into sister chromatids. The sister chromatids transform into precisely separated, mirror-like sets. Microtubules are formed into structural protein assemblies called mitotic spindles and centrioles. The mitotic spindles and centrioles perform the transformation. Malignant cells manifest abnormal segregation of chromosomes during mitosis. This is a result of malignancy in genetic mutations.

Uncorrected errors in DNA transcription due to damage to DNA contribute to malignancy. All sorts of carcinogens may damage DNA. Radiation such as x-rays or solar radiation may cause cancer. Some damage may be caused by natural accumulations of mutations through uncorrected errors in DNA transcription.

The present subject matter affects the ability of cancer cells to reproduce because ++ mitosis is prevented. Malignant cells reproduce abnormally rapidly. In normal cells a parent cell divides and forms two daughter cells. The daughter cells may build new tissue or replace dead cells. Normal cells cease mitosis when daughter cells are not needed. However, cancer cells continue uncontrolled mitosis.

The base pairs 660 in cancer cells take on a configuration that is different from the configuration of base pairs 660 in a normal cell. For this reason, the base pairs 660 in the normal cells are not affected while the cancerous cells are treated. Research has revealed that chromosomal differences are present in cancer cells.

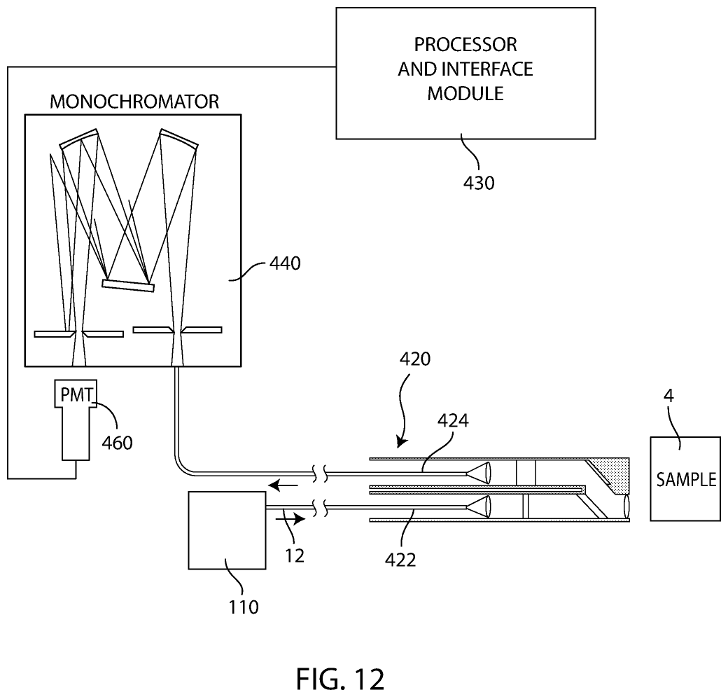

FIG. 12 illustrates a device used in detection of tumors. In the present illustration, the sample 4 is an in vivo mass of tissue that is being tested. The test is a spectrophotgraphic analysis. A biopsy is avoided. This eliminates the risk of spreading cancer cells to adjoining tissue or into the blood stream.

A transmission package 10 (FIG. 1) is delivered in the laser beam 12 via a Raman probe 420 to the sample 4. The Raman probe 420 includes an input optical fiber 422 and an output optical fiber 424. The input optical fiber 422 delivers the laser beam 12 from the laser module 110 (FIG. 1). The output optical fiber 424 delivers an output from the Raman probe 420 to the monochromator 440. The Raman probe is useful in measuring Raman shift including anti-Stokes and Stokes responses. The wavelengths of excitation radiation may be different from the preferred values used in Raman spectroscopy. Return transmission is gathered from the sample 4 by the Raman probe 420 and coupled to the monochromator 440. The monochromator 440 delivers an output that is sensed by a photomultiplier tube 460. The photomultiplier tube 460 provides outputs indicative of intensity at each of a plurality of successive wavelengths. Signals are provided to a processor and interface module 430.

Many functions may be provided by the processor and interface module 430. Generated spectra are preferably stored. Each spectral distribution may be compared to stored values indicative of peaks corresponding to particular bonds. Entire spectra may be compared to each other to indicate differences between first and second scanned samples. The information provided to the processor and the interface module 430 may be archived and used to generate further correlations between observed data and physical attributes of materials.

FIG. 13 is a graph showing spectra which differentiate normal cells from cancer cells. The spectra of FIG. 13 are generated by 5 FU spectroscopy. 5 FU has separate spectra before and after irradiation. The fine line plot 700 is the spectrum for a normal cell. The bold line plot 710 is the spectrum for a cancerous cell. Peaks at various wave lengths are associated with particular bonds. Commonly used peak values and the bonds that they indicate are illustrated in Table II. For example, the double carbonyl bond has one peak at 2800-3200 Å. The carbon-fluorine bond is a polar covalent bond between carbon and fluorine that is a component of all organofluorine compounds. It is the fourth strongest single bond in organic chemistry.

| | | |
|---|---|---|
| Wavelength - Å | Bond | Feature |

| | | | |
|---|---|---|---|
| 2800-3200 | Å | double carbonyl | 5 FU |
| | | bond | spectroscopy |
| 500-800 | cm−1 | carbon-fluorine | organofluorine |
| | | bond | compounds |

Spectra will vary for different types of cancer. However, certain distinct spectrum peaks are common to cancer cells. Therefore, it is possible to search for spectra of cancer cells. The illustrated spectra comprise nominal values and do not illustrate a specific comparison of cancerous cells to normal cells.

FIG. 14 is a diagram showing one embodiment of the present subject matter in use to treat a patient 744 for a condition in which a tumor is metastasized. A console 720 contains the laser module 2 of FIG. 1. The console 720 produces radiation coupled by a fiber optic cable 722 to a laser probe 724. Radiation exiting a laser probe tip 736 of the laser probe 724 is applied to an affected area 742 of the patient 744. The laser probe 724 carries the transmission package 10 (FIG. 1) to the laser probe 736.

A surgeon 750 manipulates the laser probe 724 in accordance with a predetermined protocol. The protocol includes parameters including distance of the laser probe tip 736 to the affected area 742, and time of application. The transmission package 10 incapacitates cancerous cells through the mechanism described with respect to FIG. 11. After treatment, the cancerous cells become static and die. The affected area 742 may be surgically removed without danger to adjoining tissue and without the risk of regrowth of cancerous cells. The transmission package 10 breaks specific locations in the DNA of FIG. 11.

In one example, a colony of pancreatic cancer cells was treated in vitro. Cancerous cells are placed into a 96-well plate, half of the samples are irradiated, the second half are control samples and are not irradiated. A dye is applied 24 hours after irradiation to all 96 wells. The live cells turn blue, showing uptake of oxygen. The dead cells do not uptake the dye and do not have color change. RNA and DNA are destroyed by irradiation. An optical well reader detected color of the cells in order to determine which cells were killed. Normal cells were also treated in vitro. Cancerous cells were killed. Normal cells were unaffected.

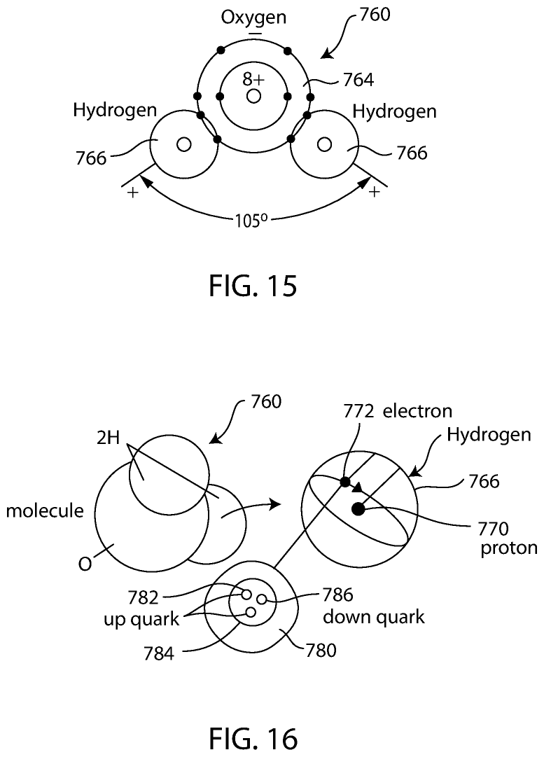

FIG. 15 illustrates a molecule 760 chosen to be the sample 4 which is to be modified by the transmission package 10 included in the laser beam 12. In the present illustration, the molecule is water, H₂O. There is a covalent bond between an oxygen atom 764 and each of two hydrogen atoms 766 in a water molecule. Each of the covalent bonds contains two electrons, one from a hydrogen atom and one from the oxygen atom. Both atoms share the electrons.

FIG. 16 illustrates a sample which has been modified by the transmission package. In the molecule 760, a hydrogen atom 766 has a proton 770 at its nucleus. An electron 772 orbits the proton 770. The transmission package 10 comprises entities that interact with the molecule wherein the molecule is modified. Interaction with dark matter cannot be explained at the present time. However, interaction is observed. This interaction is repeatable. While the mechanism is not known, it is believed that dark matter in the transmission package 10 affects quarks within the atom 766. In particular, a quark 780 is included in the electron 772. The quark 780 comprises first and second up quarks 782 and 784 and a down quark 786. The relativistic observation could be made that the transmission package 10 has punched a hole through time into the sample. It is believed that dark matter inside an atom has a value that determines what element the atom will consist of.

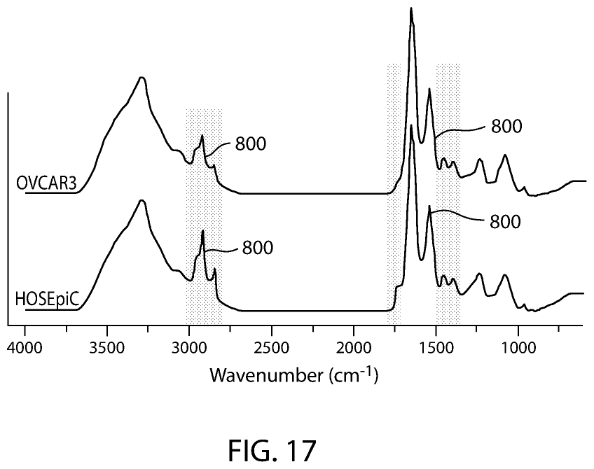

FIG. 17 is a chart of spectra indicative of differences that may occur between the original molecule of FIG. 15 and the modified molecule as seen in FIG. 16. This comparison indicates changes in bonds between components of the molecule. In particular height and width of peaks 800 will vary. A comparison of the type illustrated in FIG. 17 will be obtained by the spectrum generation.

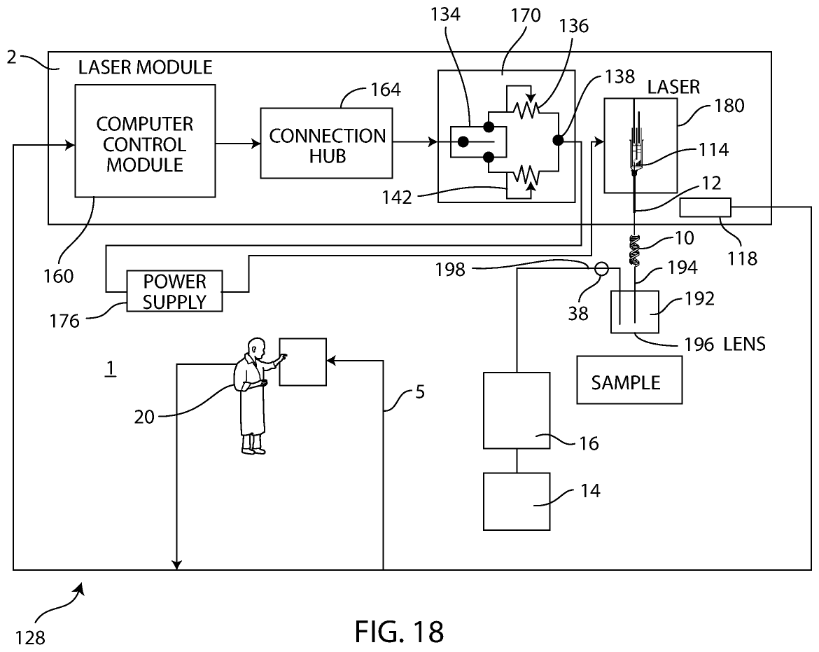

FIG. 18 is a block diagram of another embodiment of the present subject matter. The same reference numerals are used to denote components corresponding to those in FIG. 1. The laser module 2 comprises a computer control module 160 providing timing signals to a connection hub 164. The connection hub 164 may comprise a National Instruments connection hub. The connection hub comprises a switching circuit 170. The switching circuit 170 responds to inputs from the computer control module 160 to provide a first or a second voltage signal to a power supply 176. The power supply 176 is connected to provide a first level of current to a laser 180 in response to the first voltage signal from the power supply 176. This current level places the laser 180 into a sublasing state. The power supply 176 is connected to provide a second level of current to the laser 180 in response to the second voltage signal from the power supply 176. The second level of current triggers the laser 180. The laser beam 12 is carried by an excitation fiber 194 to a Raman probe 192. A lens 196 focuses the laser beam on the sample 4. A nominal focal length for the lens 196 is 5 mm. The focal length of the lens can exceed 500% or more. The Raman probe 192 has a collection fiber 198. In this mode, the laser beam 12 is used to excite the sample 4 and cause a structural change. Normally, spectrographic analysis is not performed. In a calibration mode, the collection fiber 198 collects an emission package output 38. The emission package output 38 is coupled to the monochromator 16 and the spectrometer 14.

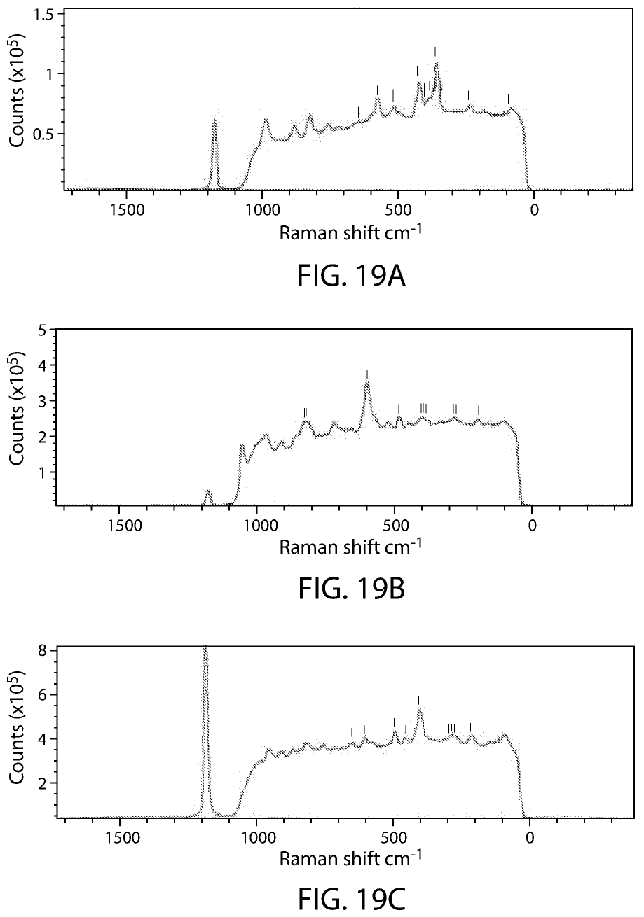

FIG. 19, consisting of FIGS. 19A, 19B, and 19C, comprises charts illustrating nominal results obtained from the spectrometer 14 of FIG. 1. These charts can be used to build a library of reference spectra. The spectra may comprise information for different categories of samples. FIGS. 19A, 19B and 19C each represent a spectrum for a different species of cancer cell. The characteristic peaks uniquely associated with each type of cell are used to identify the identity of material in the sample 4.

Although the foregoing description has specified certain steps and apparatus that may be used in employing the present subject matter, those skilled in the art will appreciate that many modifications and substitutions may be made. Accordingly, it is intended that all such modifications, alterations, substitutions and additions should be considered to fall within the spirit and scope of the present subject matter. Therefore, it is appreciated that the figures provided herein illustrate only portions of solid-state laser circuitry that pertain to the practice of the present subject matter. Thus, the present subject matter is not limited to the structures described herein.

1. A spectroscopy platform comprising:
a. a control module providing a signal indicative of a photomultiplier output;
b. a threshold circuit, said threshold circuit providing a first voltage signal responsive to a photomultiplier output below a preselected level and a second voltage signal responsive to a photomultiplier output at or above the preselected level;
c. a power supply responsively coupled to said threshold circuit, said power supply providing a first current in response to the first voltage signal and providing a second current in response to the second voltage signal;
d. a quantum well laser coupled for biasing by said power supply, said laser being biased to a sublasing stage in response to the first current and being triggered by the second current, said quantum well laser forming a transmission package in the sublasing stage and transmitting the transmission package in response to the laser being triggered;
e. a Raman probe coupled to direct the transmission package to a sample and for receiving an emission package from the sample, the emission package being coupled to a monochromator comprising a diffraction grating and spectrometer, said photomultiplier providing an output to said control module.

2. A method for performing non Raman spectroscopy comprising the steps of;
a. providing a quantum well laser;
b. sequentially biasing the quantum well laser to a sublasing stage with a first current and triggering the quantum well laser with a second current;
c. allowing formation of a transmission package in a quantum well of the quantum well laser through inherent operation of a quantum well laser;
d. coupling a laser beam including the transmission package to a Raman probe;
e. positioning the Raman probe to transmit the transmission package and receive an emission package comprising a unidirectional response from a sample position;
f. coupling the emission package to a diffraction grating monochromator to produce spectral responses;
g. measuring the spectral responses with a photomultiplier: and
h. sending a photomultiplier output to close a loop with the power supply coupled to said laser.
